(19) United States
(12) Patent Application Publication
(10) Pub. No.: US 2024/0020899 A1
(43) Pub. Date: Jan. 18, 2024

(54) DISPLAY METHOD AND INFORMATION PROCESSING APPARATUS

(71) Applicant: Tokyo Electron Limited, Tokyo (JP)

(72) Inventors: Ryota AOI, Hokkaido (JP); Kenichi KOBAYASHI, Hokkaido (JP)

(21) Appl. No.: 18/218,450

(22) Filed: Jul. 5, 2023

(30) Foreign Application Priority Data
Jul. 12, 2022 (JP) 2022-111762

(51) Int. Cl. G06T 13/00; G06T 11/20; G08B 29/00

(52) U.S. Cl. CPC G06T 13/00; G06T 11/206; G08B 29/00

(57) ABSTRACT

A display method includes acquiring history information of data, including sensor data detecting a state of a substrate processing apparatus and image data displaying the state of the substrate processing apparatus, from a plurality of pieces of data managed by the substrate processing apparatus; acquiring alarm information including a date and time of occurrence at which a specific event occurred in the substrate processing apparatus; determining, as trace information to be displayed, sensor data for a specific period including the date and time of occurrence included in the alarm information, among the history information of the data; determining, as video image information to be displayed, image data for the specific period including the date and time of occurrence included in the alarm information, among the history information of the data; and displaying, on a display, at least one of the trace information and the video image information.

### CROSS-REFERENCE TO RELATED APPLICATIONS

The present application is based on and claims priority from Japanese Patent Application No. 2022-111762, filed on Jul. 12, 2022, with the Japan Patent Office, the disclosure of which is incorporated herein in its entirety by reference.

### TECHNICAL FIELD

The present disclosure relates to a display method and an information processing apparatus.

### BACKGROUND

Japanese Patent Laid-Open Publication No. 2008-198796 proposes, for example, that an operation target object for which an operation may be set, among components of a substrate processing apparatus, and a screen related to the setting of an operation thereof are associated with each other and are stored in a screen memory, and when the operation target object is specified by a manipulation while a video image of the operation target object is being displayed on an operation manipulation display, a setting screen related thereto is retrieved from the screen memory and is displayed on the operation manipulation display.

### SUMMARY

According to an aspect of the present disclosure, a display method includes acquiring history information of data, including sensor data detecting a state of a substrate processing apparatus and image data displaying the state of the substrate processing apparatus, from a plurality of pieces of data managed by the substrate processing apparatus, acquiring alarm information including a date and time of occurrence at which a specific event occurred in the substrate processing apparatus, determining, as trace information to be displayed, sensor data for a specific period including the date and time of occurrence included in the alarm information, among the history information of the data, determining, as video image information to be displayed, image data for the specific period including the date and time of occurrence included in the acquired alarm information, among the history information of the data, and displaying, on a display, at least one of the trace information and the video image information.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a diagram illustrating a configuration example of a substrate processing system according to an embodiment.

FIG. 2 is a diagram illustrating an example of a hardware configuration of an information processing apparatus according to an embodiment.

FIG. 3 is a diagram illustrating an example of a functional configuration of the information processing apparatus according to an embodiment.

FIG. 4 is a flowchart illustrating an example of a method of saving video image information according to an embodiment.

FIG. 5 is a flowchart illustrating an example of a method of saving trace information according to an embodiment.

FIG. 6 is a flowchart illustrating an example of a display method according to an embodiment.

FIG. 7 is a display example of an alarm list according to an embodiment.

FIG. 8 is a display example of video image information of a gas flow according to an embodiment.

FIG. 9 is a display example of video image information and trace information of a gas flow according to an embodiment.

FIG. 10 is a diagram illustrating an example of a substrate processing apparatus according to an embodiment.

### DETAILED DESCRIPTION

In the following detailed description, reference is made to the accompanying drawings, which form a part thereof. The illustrative embodiments described in the detailed description, drawings, and claims are not meant to be limiting. Other embodiments may be utilized, and other changes may be made without departing from the spirit or scope of the subject matter presented here.

Hereinafter, embodiments for carrying out the present disclosure will be described with reference to the drawings. In each drawing, the same reference numerals may be given to the same components, and redundant descriptions may be omitted.

[Substrate Processing System]

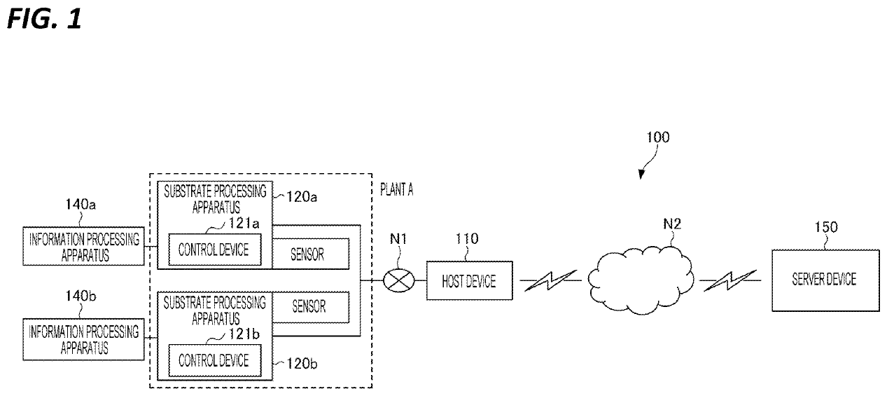

First, a configuration example of a substrate processing system according to an embodiment will be described. FIG. 1 is a diagram illustrating a configuration example of a substrate processing system 100 according to an embodiment. As illustrated in FIG. 1, the substrate processing system 100 includes, within a plant A, substrate processing apparatuses 120a and 120b and control devices 121a and 121b. The substrate processing apparatus 120a and the control device 121a are connected by wires or wirelessly. The substrate processing apparatus 120b and the control device 121b are connected by wires or wirelessly.

The control device 121a may be provided inside the substrate processing apparatus 120a. The control device 121b may be provided outside the substrate processing apparatus 120b. Further, the substrate processing system 100 may include another substrate processing apparatus and another control device within the same plant A or another plant.

The substrate processing apparatuses 120a and 120b are connected to a host device 110 via a network N1. The substrate processing apparatus 120a executes a substrate processing under the control of the control device 121a based on instructions from the host device 110. The substrate processing apparatus 120b executes a substrate processing under the control of the control device 121b based on instructions from the host device 110. The host device 110 is connected to a server device 150 via a network N2 such as the Internet. In the following description, the substrate processing apparatuses 120a, and 120b are collectively referred to as a substrate processing apparatus 120. Further, the control devices 121a and 121b are collectively referred to as a control device 121.

Multiple pieces of data, including sensor data detecting the state of the substrate processing apparatus 120 and image data (video image data) displaying the state of the substrate processing apparatus 120 on a display unit of the substrate processing apparatus 120, for example, during process execution, are managed for each substrate processing apparatus 120. Further, these multiple pieces of data are accumulated in each substrate processing apparatus 120. The multiple pieces of data managed by each substrate processing apparatus 120 include history information of each of the sensor data and the image data. The display unit which displays the state of the substrate processing apparatus 120 is the display unit of the substrate processing apparatus 120 in the present embodiment, but is not limited to this, and may be a display unit of the control device 121 or a display unit of any other device.

The control device 121 processes computer-executable instructions that cause the substrate processing apparatus 120 to execute a substrate processing of various steps such as a film formation step and an etching step. The control device 121 may be configured to control each element of the substrate processing apparatus 120 so as to execute various steps. In an embodiment, part or all of the control device 121 may be included in the substrate processing apparatus 120. The control device 121 may include a processor, a memory, and a communication interface. The control device 121 is realized by, for example, a computer. The processor may be configured to perform various control operations by reading a program from the memory and executing the read program. This program may be stored in advance in the memory, or may be acquired via a medium when necessary. The acquired program is stored in the memory, and the processor reads the program from the memory to execute the program. The medium may be any of various computer-readable storage media, or may be a communication line connected to the communication interface. The processor may be a central processing unit (CPU). The memory may include a random access memory (RAM), a read only memory (ROM), a hard disk drive (HDD), a solid state drive (SSD), or a combination thereof. The communication interface may communicate with the substrate processing apparatus 120 via a communication line such as a local area network (LAN).

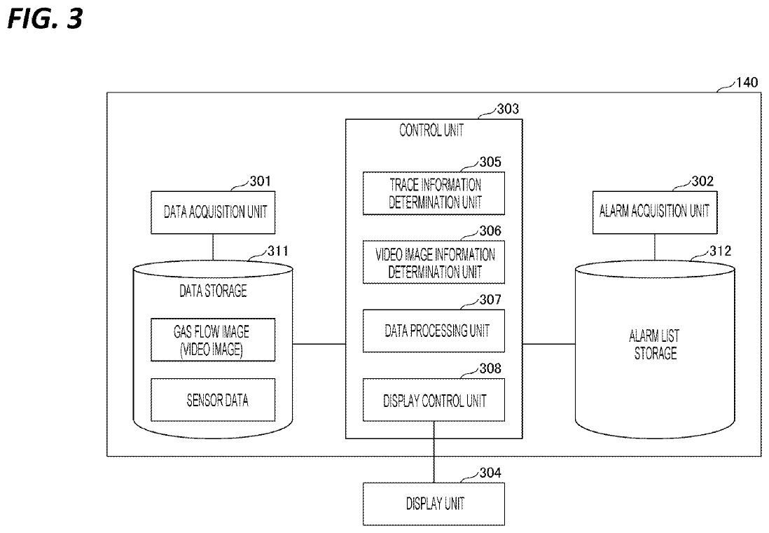

An information processing apparatus 140a is connected to the substrate processing apparatus 120a. The information processing apparatus 140a acquires the multiple pieces of data managed by the substrate processing apparatus 120a, and saves them in a data storage 311 (see FIG. 3) of the information processing apparatus 140a. An information processing apparatus 140b is connected to the substrate processing apparatus 120b. The information processing apparatus 140b acquires the multiple pieces of data managed by the substrate processing apparatus 120b, and saves them in the data storage 311 of the information processing apparatus 140b. In the following description, the information processing apparatuses 140a and 140b are collectively referred to as an information processing apparatus 140. One substrate processing apparatus 120 and one information processing apparatus 140 may be connected one-to-one, or a plurality of substrate processing apparatuses 120 and one information processing apparatus 140 may be connected many-to-one. Instead of providing the information processing apparatus 140, the host device 110 or the server device 150 may function as the information processing apparatus 140.

[Hardware Configuration of Information Processing Apparatus]

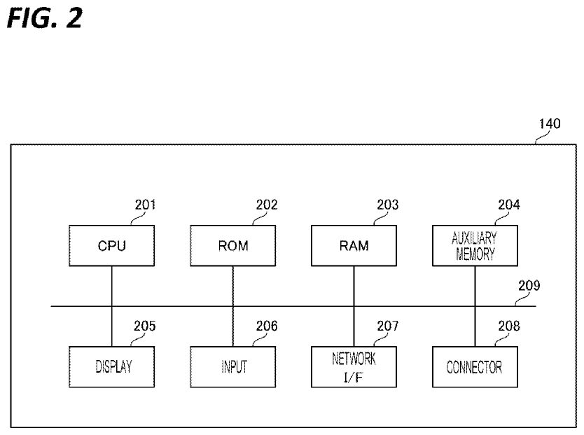

Next, a hardware configuration of the information processing apparatus 140 will be described with reference to FIG. 2. FIG. 2 is a diagram illustrating an example of a hardware configuration of the information processing apparatus 140. As illustrated in FIG. 2, the information processing apparatus 140 includes a central processing unit (CPU) 201, a read only memory (ROM) 202, and a random access memory (RAM) 203. The CPU 201, the ROM 202, and the RAM 203 form a so-called computer.

Further, the information processing apparatus 140 includes an auxiliary memory 204, a display 205, an input 206, a network interface (I/F) 207, and a connector 208. The respective pieces of hardware of the information processing apparatus 140 are interconnected via a bus 209.

The CPU 201 is a device that executes various programs (e.g., a display control program to be described later) installed in the auxiliary memory 204. The ROM 202 is a non-volatile memory. The ROM 202 functions as a main storage device that stores various programs and data required for the CPU 201 to execute various programs installed in the auxiliary memory 204. Specifically, the ROM 202 stores, e.g., a boot program such as a basic input/output system (BIOS) or an extensible firmware interface (EFI).

The RAM 203 is a volatile memory such as a dynamic random access memory (DRAM) or a static random access memory (SRAM). The RAM 203 functions as a main storage device that provides a work area that is deployed when the CPU 201 executes various programs installed in the auxiliary memory 204.

The auxiliary memory 204 is an auxiliary storage device that stores various programs and information used when the various programs are executed. The data storage 311 and an alarm list storage 312 (see FIG. 3), which will be described later, are realized in the auxiliary memory 204.

The display 205 is a display device that displays various screens. The input 206 is an input device for an operator to input various instructions to the information processing apparatus 140.

The network I/F 207 is a communication device connected to an external network (not illustrated). The connector 208 is a connection device that connects the information processing apparatus 140 to another device.

[Functional Configuration of Information Processing Apparatus]

Next, a functional configuration of the information processing apparatus 140 will be described with reference to FIG. 3. FIG. 3 is a diagram illustrating an example of a functional configuration of the information processing apparatus 140. Hereinafter, an example in which the information processing apparatus 140 (information processing apparatus 140a) performs data display control using the multiple pieces of data managed by the substrate processing apparatus 120a will be described. A case where the information processing apparatus 140 (information processing apparatus 140b) performs data display control using the multiple pieces of data managed by the substrate processing apparatus 120b is the same, and therefore, a description thereof will be omitted. As described above, the display control program is installed in the information processing apparatus 140, and by executing the display control program, the information processing apparatus 140 functions as a data acquisition unit 301, an alarm acquisition unit 302, and a control unit 303.

The data acquisition unit 301 continuously acquires specific data from the multiple pieces of data managed by the substrate processing apparatus 120 and stores it in the data storage 311. The data storage 311 stores the specific data managed by the substrate processing apparatus 120a.

The specific data acquired by the data acquisition unit 301 includes sensor data detecting the state of the substrate processing apparatus 120a and image data displaying the state of the substrate processing apparatus 120a on a display screen of the display unit 304 of the substrate processing apparatus 120a. In this example, the image data is a video image (animation) displaying the state of a gas flow through a plurality of gas supply pipes of the substrate processing apparatus 120a, on the screen of the display unit 304 of the substrate processing apparatus 120a during a process.

The data managed by the substrate processing apparatus 120a includes, for example, sensor data indicating the state of the substrate processing apparatus 120a detected by a sensor attached to the substrate processing apparatus 120a. The sensor data is a detected value of the sensor attached to the substrate processing apparatus 120a. Examples of the sensor data may include various types of data such as a heater temperature, pressure, gas type, gas flow rate, RF power, valve opening degree, luminescence intensity, time of each step of the process, temperature increase rate, and/or temperature decrease rate. Examples of the sensor may include a temperature sensor, pressure sensor, mass flow controller, and plasma emission monitor.

Further, the data managed by the substrate processing apparatus 120a may include video images indicating the state of transfer such as the positions and operations of forks and arms of a substrate transfer device, and other data such as torques applied to substrate lifting pins. The data storage 311 may store the video images indicating the state of transfer such as the positions and operations of the forks and arms of the substrate transfer device as history information of the image data, and the data such as the torques applied to the substrate lifting pins as history information of the sensor data.

The alarm acquisition unit 302 continuously acquires alarm information issued when a specific event occurred in the substrate processing apparatus 120a, and stores it in the alarm list storage 312. The alarm information includes information on the date and time of occurrence when the specific event occurred. The alarm list storage 312 stores a list of the alarm information including the date and time of occurrence when the specific event occurred in the substrate processing apparatus 120a. In the example, the “specific event” is a trouble occurred in the substrate processing apparatus 120a, and a description will be continued with the date and time of occurrence when the specific event occurred as the date and time of trouble occurrence. However, the specific event is not limited to the trouble occurrence, and may be, for example, a trouble warning or a specific incident.

The control unit 303 includes a trace information determination unit 305, a video image information determination unit 306, a data processing unit 307, and a display control unit 308. The trace information determination unit 305 determines, as trace information to be displayed, sensor data for a specific period including the date and time of trouble occurrence included in the acquired alarm information, among the history information of the data stored in the data storage 311. For example, the trace information determination unit 305 determines, as trace information to be displayed, sensor data for 2 minutes before and 2 minutes after the trouble occurrence from the date and time of trouble occurrence included in the acquired alarm information, among the history information of the data stored in the data storage 311.

The video image information determination unit 306 determines, as video image information to be displayed, image data for a specific period including the date and time of trouble occurrence included in the acquired alarm information, among the history information of the data stored in the data storage 311. For example, the video image information determination unit 306 determines, as video image information to be displayed, video image data of the gas flow state for 2 minutes before and 2 minutes after the trouble occurrence from the date and time of trouble occurrence included in the acquired alarm information, among the history information of the data stored in the data storage 311. The video image data is an animation that displays an operation in which the gas flow state varies over time as a time series.

The data processing unit 307 performs a data processing so as to link the trace information and the video image information within a specific period. For example, the data processing unit 307 may perform a data processing so as to link the trace information and the video image information at the same timestamp within a specific period.

The display control unit 308 displays at least one of the determined trace information and video image information on the display. For example, the display control unit 308 may display, on the display unit 304 of the substrate processing apparatus 120a, a display component for which a specific timestamp within a specific period may be designated as well as trace information and video image information at the specific timestamp designated by manipulating the display component.

The display control unit 308 may display the trace information and the video image information in separate windows. The display component may be a display object indicating a specific period on a bar-shaped time axis. The trace information and the video image information at the specific timestamp designated by touching or shifting the bar-shaped time axis of the display component may be displayed on the display unit 304 of the substrate processing apparatus 120a in conjunction with each other.

When a trouble occurs in the substrate processing apparatus 120a, the cause of the trouble may be identified from trace information around the date and time of occurrence. The trace information is data indicating history information of sensor data (e.g., temperature and gas flow rate) of various sensors attached to the substrate processing apparatus 120.

In the substrate processing apparatus 120a, there are many cases where a part that issues, e.g., an alarm is not the direct cause of a trouble. Further, since the substrate processing apparatus 120a is equipped with a large number of sensors and control targets, it is required to roughly identify a part that caused a trouble from a large amount of sensor data. However, the task of organizing trace information itself is laborious and hinders the rapid identification of the cause. Further, in order to identify the true cause, an environment is required in which a situation around the substrate processing apparatus 120a may be confirmed together with the trace information.

Therefore, in the present embodiment, the cause of the trouble is identified by the trace information and the video image information indicating the gas flow state before and after the trouble occurrence. The trace information uses history information of selected sensor data for a specific period. The video image information of a gas flow is an animation (video image information) that indicates the extent to which a specific gas flowed through the gas supply pipe during a specific period.

In a display method according to the present embodiment, trace information for about 2 minutes before and after the trouble occurrence and a gas flow animation (video image information) may be automatically extracted and be displayed in conjunction with time. Due to the operator's ability to refer to both the trace information and the video image information of the gas flow state in a unified manner and the ability to omit the laborious task of organizing these information, prompt identification of the cause may be achieved.

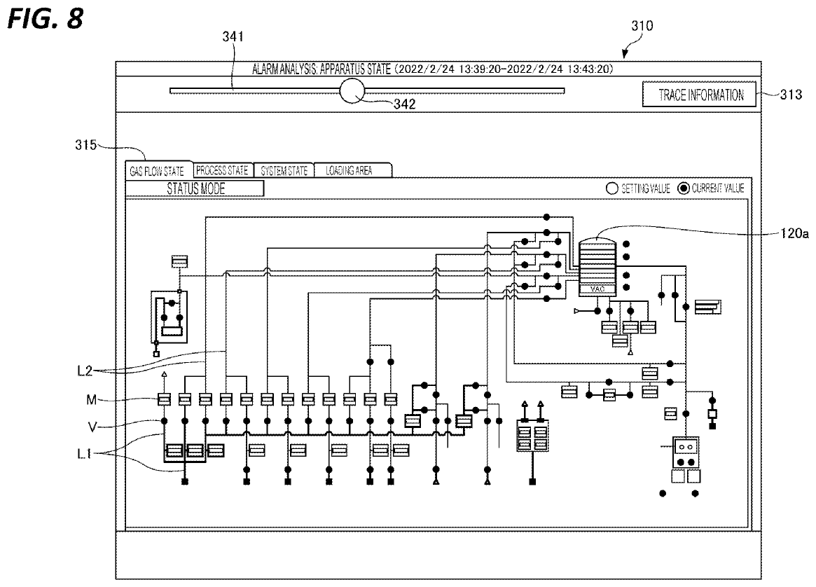

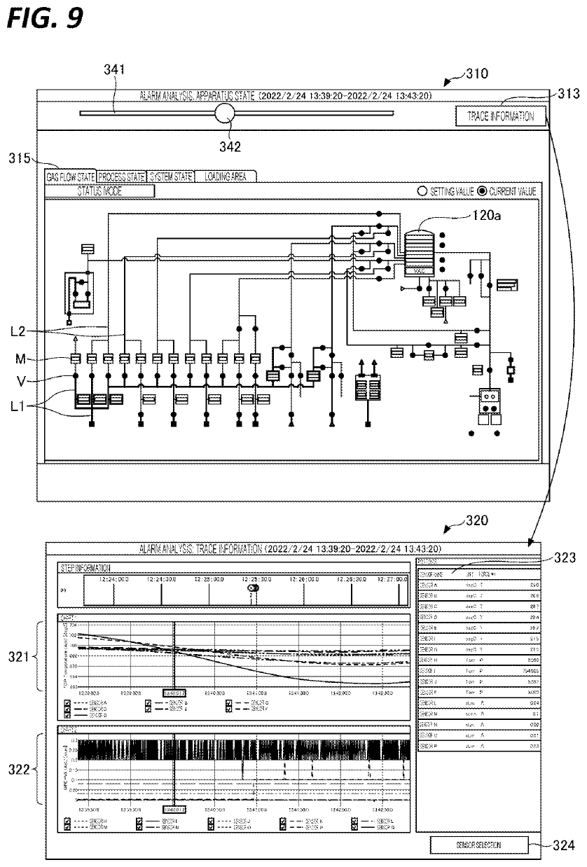

Further, the displayed video image information of a gas flow is the same as that displayed on the display screen of the display unit 304 of the substrate processing apparatus 120a during the process (see FIGS. 8 and 9). Thus, the operator may check the state of the apparatus before and after the trouble occurrence in a familiar display environment. By limiting information to be displayed to the information before and after the date and time of trouble occurrence, it becomes easier to find the cause of the trouble, and there is no waste in the data capacity being used.

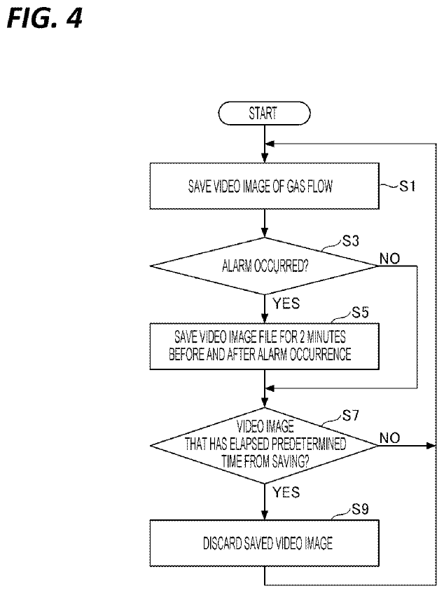

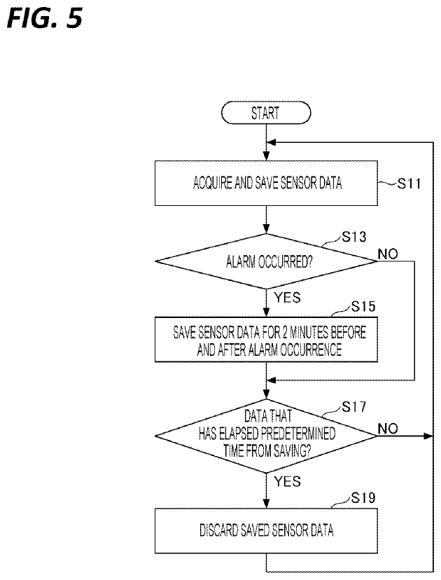

Hereinafter, before describing an example of the display method according to the present embodiment, an example of a method of saving video image information according to an embodiment will be described with reference to FIG. 4. Further, an example of a method of saving trace information according to an embodiment will be described with reference to FIG. 5. FIG. 4 is a flowchart illustrating an example of a method of saving video image information according to an embodiment. FIG. 5 is a flowchart illustrating an example of a method of saving trace information according to an embodiment. The information processing apparatus 140 controls the method of saving video image information of FIG. 4 and the method of saving trace information of FIG. 5.

[Method of Saving Video Image Information]

First, a method of saving video image information of a gas flow displayed on the display unit 304 of the substrate processing apparatus 120a will be described. First, in step S1 of FIG. 4, the data acquisition unit 301 acquires video image information of a gas flow displayed on the display unit 304 from the substrate processing apparatus 120a or the control device 121a, and saves it in the data storage 311.

Next, in step S3, the alarm acquisition unit 302 determines whether an alarm has occurred based on the acquired alarm information. When it is determined that an alarm has occurred, in step S5, the video image information determination unit 306 creates a video image file of the gas flows for 2 minutes before and after the alarm occurrence based on the date and time of alarm occurrence included in the alarm information. The video image information determination unit 306 saves the created video image file, and proceeds to step S7. A saving location of the video image file may be a memory area of the information processing apparatus 140, for example, the RAM 203 or the auxiliary memory 204.

Meanwhile, in step S3, the alarm acquisition unit 302 proceeds to step S7 when it is determined that no alarm has occurred. In step S7, the data processing unit 307 determines whether there is any video image information that has passed a predetermined time since saving among the video image information saved in the data storage 311. When it is determined that there is no video image information that has passed the predetermined time since saving, the data processing unit 307 returns to step S1, and continues the processing from step S1 onwards. Meanwhile, in step S7, when it is determined that there is video image information that has passed the predetermined time since saving, the data processing unit 307 proceeds to step S9. In step S9, the data processing unit 307 discards from the data storage 311 the video image information that has passed the predetermined time since saving, and then returns to step S1 and continues the processing from step S1 onwards. The predetermined time is set in advance.

[Method of Saving Trace Information]

Next, a method of saving sensor data detected by various sensors attached to the substrate processing apparatus 120a will be described. First, in step S11 of FIG. 5, the data acquisition unit 301 acquires sensor data detected by various sensors from the substrate processing apparatus 120a or the control device 121a, and saves it in the data storage 311.

Next, in step S13, the alarm acquisition unit 302 determines whether an alarm has occurred based on alarm information. When it is determined that an alarm has occurred, the alarm acquisition unit 302 proceeds to step S15. In step S15, the trace information determination unit 305 determines, as trace information, sensor data for 2 minutes before and after the alarm occurrence based on the date and time of alarm occurrence included in the alarm information. The trace information determination unit 305 saves the determined trace information, and proceeds to step S17. A saving location of the trace information may be a memory area of the information processing apparatus 140, for example, the RAM 203 or the auxiliary memory 204.

Meanwhile, in step S13, when it is determined that no alarm has occurred, the alarm acquisition unit 302 proceeds to step S17. In step S17, the data processing unit 307 determines whether there is any sensor data that has passed a predetermined time since saving among the sensor data saved in the data storage 311. When it is determined that there is no sensor data that has passed the predetermined time since saving, the data processing unit 307 returns to step S11, and continues the processing from step S11 onwards. Meanwhile, in step S17, when it is determined that there is sensor data that has passed the predetermined time since saving, the data processing unit 307 proceeds to step S19. In step S19, the data processing unit 307 discards from the data storage 311 the sensor data that has passed the predetermined time since saving, and then returns to step S11 and continues the processing from step S11 onwards. The predetermined time is set in advance.

[Display Method]

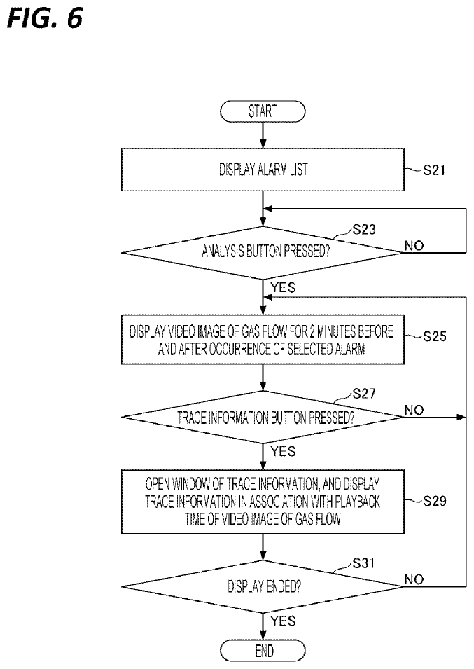

Next, a method of displaying a saved video image file (video image information) and trace information will be described with reference to FIGS. 6 to 9. FIG. 6 is a flowchart illustrating an example of a display method according to an embodiment.

When the process of FIG. 6 starts, in step S21, the alarm acquisition unit 302 displays a list of alarm information stored in the alarm list storage 312.

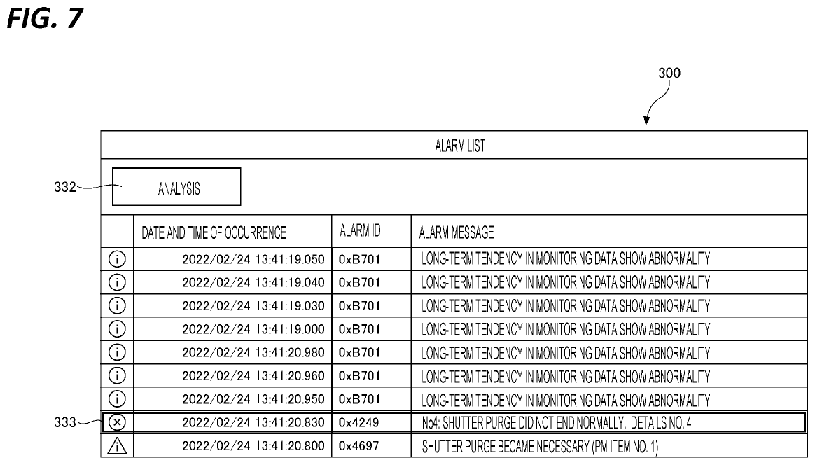

FIG. 7 is a display example of a list of alarm information according to an embodiment. On a screen 300 displaying the list of alarm information, the date and time of occurrence, alarm ID, and alarm message for each alarm are displayed as the alarm information. Specific alarm information may be selected from the displayed alarm information. On the screen 300, a second piece of alarm information 333 from below is selected. Further, an analysis button 332 is displayed on the screen 300.

Referring back to FIG. 6, next, in step S23, the display control unit 308 determines whether the analysis button 332 has been pressed. The display control unit 308 waits until the analysis button 332 is pressed, and proceeds to step S25 when it is determined that the analysis button 332 has been pressed. In step S25, the display control unit 308 displays video image information of the gas flow state for 2 minutes before and 2 minutes after the trouble occurrence indicated by the selected alarm information based on a video image file created for the selected alarm information.

FIG. 8 is a display example of video image information of a gas flow according to an embodiment. In a screen 310, a tab 315 for the gas flow state is selected, and screen data of the gas flow is displayed below the tab 315.

At the top of the screen 310, a display component 341 capable of designating a specific timestamp within a specific period (e.g., 2 minutes before and after the trouble occurrence) is displayed. The display component 341 represents a bar-shaped time axis. The left end of the display component 341 is 2022/2/24 13:39:20, and the right end is 2022/2/24 13:43:20. The center of the bar-shaped display component 341 is 2022/2/24 13:41:20, which is the date and time of trouble occurrence indicated in the selected alarm information in FIG. 7.

That is, the video image information of a gas flow may be displayed as a video image (animation) of the gas flow state for 2 minutes before and after the trouble occurrence, for a total of 4 minutes, saved in a video image file. Further, the gas flow state at a designated timestamp in the video image file for 2 minutes before and after the trouble occurrence may be displayed. For example, the gas flow state at a timestamp the operator wants to watch may be displayed as the operator touches a button 342 which is movable from the left end to the right end of the bar-shaped time axis of the display component 341. In the example of FIG. 8, the gas flow state near a trouble occurrence timestamp is displayed as the operator touches the button 342.

As illustrated in FIG. 8, the image of the gas flow state schematically shows an actual gas path from a gas source to the substrate processing apparatus 120a, and contains, for example, gas supply pipes L1 and L2, a mass flow controller M, and a valve V. The gas supply pipe L1 is represented by a thicker line than the gas supply pipe L2, indicating that a gas is flowing through the gas supply pipe L1 at the timestamp indicated by the button 342. The gas supply pipe L2 is represented by a thin line, indicating that no gas is flowing through the gas supply pipe L2 at this timestamp. That is, since the valve V is closed, the gas does not flow to the gas supply pipe L2. However, whether or not the gas is flowing is not limited to being indicated by the thickness of the line, but may be indicated by other methods such as changing the color of the line. Since the gas will be supplied up to the gas supply pipe L2 beyond the valve V when the valve V is opened, the display of the gas supply pipe will change. By reproducing the gas flow state as the video image in this way, the operator may easily observe a temporal change in the gas flow before and after the trouble occurrence.

As for the flow rate of the gas flowing through the gas supply pipe L1, it is designed to display a value of the gas flow rate on the illustrated mass flow controller M, allowing the gas flow rate through each gas supply pipe to be known at each point in time.

When the operator touches the button 342 and shifts it left or right, the gas flow state before or after the shifted timestamp may be reproduced as a video image. In the present embodiment, the gas flow state is displayed using the format of a screen displayed on the display unit 304 during the process of the substrate processing apparatus 120a. Thus, the operator may visually verify, on the same screen that displays a typical gas flow state used during regular processes, for example, up to which point the gas is being supplied in the gas supply pipe at a certain point in time, the flow rate of the gas being supplied, and the open or closed state of each valve. This makes it possible to more easily analyze the cause of an alarm.

Referring back to FIG. 6, next, in step S27, the display controller 308 determines whether a trace information button 313 has been pressed. When it is determined that the trace information button 313 has not been pressed, the display controller 308 returns to step S25 and continues the processing from step S25 onwards.

In step S27, when it is determined that the trace information button 313 has been pressed, the display controller 308 proceeds to step S29. In step S29, the display controller 308 opens a window displaying trace information, and synchronizes it with the playback time of the video image indicating the gas flow state, and then displays the trace information in another window.

Next, in step S31, the display controller 308 determines whether to end the display of the gas flow state. When it is determined to end the display of the gas flow state according to the operator's manipulation, the display controller 308 ends this processing. When it is determined not to end the display of the gas flow state, the display controller 308 returns to step S25 and continues the processing after step S25 onwards.

FIG. 9 is a display example of video image information of a gas flow and trace information according to an embodiment when the window displaying trace information is opened in step S29. When the trace information button 313 is pressed, another window 320 is opened. The display controller 308 displays trace information of a selected sensor 323 as graphs 321 and 322. Selection of the sensor 323 may be performed by pressing a sensor selection button 324.

The trace information is displayed in conjunction with a video image illustrating the gas flow state. On the screen 310, screen data of a gas flow at the timestamp indicated by the button 342 in FIG. 8 is displayed. At this time, in the example of FIG. 9, the trace information is represented, and the position of the trace information at the timestamp indicated by the button 342 is represented on the graph with a vertical thick line. The window 320 may be displayed within the screen 310, or may be displayed on another screen transitioned from the screen 310. When the timestamp indicated by the position of the button 342 changes, video image information of a gas flow changed in conjunction with the timestamp indicated by the position of the button 342 is displayed. Also, the position of the trace information represented by the vertical thick line is changed in conjunction with the timestamp indicated by the position of the button 342 to indicate the timestamp.

Thus, the operator may simultaneously view the gas flow state at a specified timestamp and the trace information at the same timestamp, allowing for a more efficient understanding of the situation before and after the trouble occurrence by referring to both pieces of information. Further, sensor data may be displayed divided into multiple graphs according to the scale, or multiple pieces of sensor data may be displayed on the same graph, enabling the efficiency improvement of alarm analysis tasks.

According to the display method of the present disclosure described above, it is possible to improve the efficiency of displaying required history information for checking the state of the substrate processing apparatus 120 upon trouble occurrence. Further, by displaying the history information, including the video image information of a gas flow and the trace information in conjunction with each other, required for checking the state of the substrate processing apparatus 120 upon trouble occurrence, it is easier to identify the cause of the trouble occurrence.

[Modification]

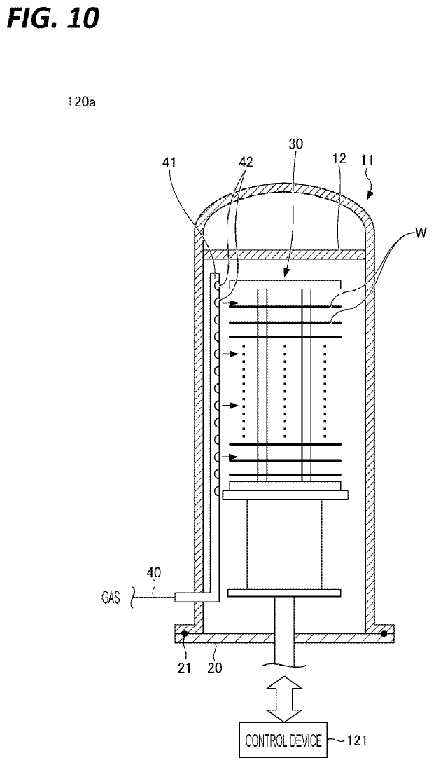

In the above, displaying the image information and trace information of the gas flow has been described by way of example. In a modification, video image information and trace information of the state of a substrate on a substrate holder 30 are displayed. A simplified example of the substrate processing apparatus 120a is illustrated in FIG. 10. The substrate processing apparatus 120a includes a chamber 11, a gas supply device 40, and the control device 121. The gas supply device 40 of the substrate processing apparatus 120a includes a gas nozzle 41. The gas nozzle 41 has a plurality of gas holes 42.

A ceiling plate 12 is provided near an upper end inside the chamber 11, and a region below the ceiling plate 12 is sealed. The chamber 11 and the ceiling plate 12 are made of, for example, quartz, and accommodate the substrate holder 30. A cylindrically molded lid 20 is connected to an opening at a lower end of the chamber 11 via a sealing member 21 such as an O-ring.

The substrate holder 30 holds a plurality of (e.g., 25 to 150) substrates W, for example, wafers on a shelf. The substrate holder 30 is made of, for example, quartz. The substrate holder 30 supports the plurality of substrates W by three pillars. The substrate holder 30 and the lid 20 are integrally raised and lowered by an elevation mechanism (not illustrated) so as to be inserted into and separated from the chamber 11.

A transfer device uses arms to take out the substrate W from a cassette placed on a load port (not illustrated) and to place the substrate W on the shelf of the substrate holder 30 through a transfer chamber. For example, a display screen displaying the state of the substrate placed on the substrate holder 30 illustrated in FIG. 10 is displayed on the display unit 304 of the substrate processing apparatus 120a, and video image information of the state of the substrate on the substrate holder 30 is stored in the data storage 311.

In the modification, the video image information of the substrate holder 30 on the display screen is displayed in conjunction with trace information. Thus, upon trouble occurrence, it is possible to easily visually grasp where the substrate W is placed on the substrate holder 30. Further, by displaying the placement state of the substrate on the substrate holder 30 in conjunction with the trace information, it is possible to promptly and efficiently identify the cause of a trouble occurred in the substrate or in the transfer state, for example, in the event of an earthquake, and subsequently to implement required recovery measures with ease. Along with the video image information of the state of the substrate on the substrate holder 30, video image information indicating the transfer state such as the positions and operations of the forks and arms of the substrate transfer device may be used.

As described above, according to the display method and the substrate processing apparatus of the present embodiment, it is possible to improve the efficiency of displaying required history information for checking the state of the substrate processing apparatus.

The substrate processing apparatus of the present disclosure is not limited to the apparatus illustrated in FIG. 10. The substrate processing apparatus is applicable to any type of apparatus such as an atomic layer deposition (ALD), capacitively coupled plasma (CCP), inductively coupled plasma (ICP), radial line slot antenna (RLSA), electron cyclotron resonance plasma (ECR), or helicon wave plasma (HWP) apparatus.

Needless to say, the substrate processing system 100 of the present disclosure is not limited to the system illustrated in FIG. 1, and there are various system configuration examples depending on the purpose or objective.

The substrate processing apparatus of the present disclosure may be applied to any of a single wafer apparatus for processing substrates one by one, and a batch apparatus and a semi-batch apparatus for collectively processing a plurality of substrates.

A substrate processing performed by the substrate processing apparatus of the present disclosure may include, for example, a film formation processing and an etching processing.

According to an aspect, it is possible to improve the efficiency of displaying required history information for checking the state of a substrate processing apparatus.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A display method comprising:
acquiring history information of data including sensor data detecting a state of a substrate processing apparatus and image data displaying the state of the substrate processing apparatus, from a plurality of pieces of data managed by the substrate processing apparatus;
acquiring alarm information including a date and time of occurrence at which a specific event occurred in the substrate processing apparatus;
determining, as trace information to be displayed, sensor data for a specific period including the date and time of occurrence included in the alarm information, among the history information of the data;
determining, as video image information to be displayed, image data for the specific period including the date and time of occurrence included in the alarm information, among the history information of the data; and
displaying, on a display, at least one of the trace information and the video image information.

2. The display method according to claim 1, wherein the trace information and the video image information within the specific period are displayed in conjunction with each other.

3. The display method according to claim 2, wherein the trace information and the video image information at a same timestamp within the specific period are displayed in conjunction with each other.

4. The display method according to claim 1, further comprising:
displaying a display component capable of designating a specific timestamp within the specific period; and
displaying the trace information and the video image information at the specific timestamp designated by manipulating the display component.

5. The display method according to claim 4, wherein the trace information is displayed in a window different from a window of the video image information, and
the display component indicates the specific period on a time axis, and
the display of the trace information and video image information are changed in conjunction with a change in the specific timestamp designated by manipulating the time axis.

6. An information processing apparatus comprising:
a data acquisition circuitry configured to acquire history information of data including sensor data detecting a state of the substrate processing apparatus and image data displaying the state of the substrate processing apparatus, from a plurality of pieces of data managed by the substrate processing apparatus;
an alarm acquisition circuitry configured to acquire alarm information including a date and time of occurrence at which a specific event occurred in the substrate processing apparatus;
a trace information determination circuitry configured to determine, as trace information to be displayed, sensor data for a specific period including the date and time of occurrence included in the alarm information, among the history information of the data;
a video image information determination circuitry configured to determine, as video image information to be displayed, image data for the specific period including the date and time of occurrence included in the alarm information, among the history information of the data; and
a display control circuitry configured to display, on a display, at least one of the trace information and the video image information.
